(19) United States
(12) Patent Application Publication
(10) Pub. No.: US 2011/0215687 A1
(43) Pub. Date: Sep. 8, 2011

(54) APPARATUS WITH CASE

(75) Inventors: YUN-LUNG CHEN, Tu-Cheng (TW); ZHAO-BIN YANG, Shenzhen City (CN); WEI-YONG MA, Shenzhen City (CN)

(73) Assignees: HONG FU JIN PRECISION INDUSTRY (ShenZhen) CO., LTD, Shenzhen City (TW); HON HAI PRECISION INDUSTRY CO., LTD., Tu-Cheng (TW)

(21) Appl. No.: 12/894,253

(22) Filed: Sep. 30, 2010

(30) Foreign Application Priority Data
Mar. 5, 2010 (CN) 201010118642.3

(51) Int. Cl. H05K 5/02

(52) U.S. Cl. 312/223.2

(57) ABSTRACT

An apparatus includes a case and a bezel. The case includes a wall. A wall flange is located on the wall. A plurality of pairs of cutouts is defined in an edge of the wall flange, and an extending tab is located between each pair of cutouts. A plurality of locking members is located on the bezel, the locking members engaged in the receiving openings.

### CROSS-REFERENCE TO RELATED APPLICATIONS

This application is related to co-pending application entitled, “APPARATUS WITH CASE”, filed on Sep. 24, 2010, application Ser. No. 12/889,548, (Atty. Docket No. US32738).

### BACKGROUND

1. Technical Field

The present disclosure relates to an apparatus with a case, which has improved electronic magnetic interference (EMI)-resistant capability.

2. Description of Related Art

EMI exists in many electronic devices, such as computer systems. Therefore, an apparatus should be designed to reduce EMI from harming users or interference with other electronic device, so there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an apparatus in accordance with an embodiment, and doesn't show a cover.

FIG. 2 is a partially cut-away, enlarged view of portion II of the apparatus of FIG. 1.

FIG. 3 is an assembled view of the electronic apparatus of FIG. 1.

FIG. 4 is similar to FIG. 3, and shows the cover.

FIG. 5 is a cross-section view of FIG. 4 along a direction V-V line.

FIG. 6 is a cross-section view of FIG. 4 along a direction VI-VI line.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

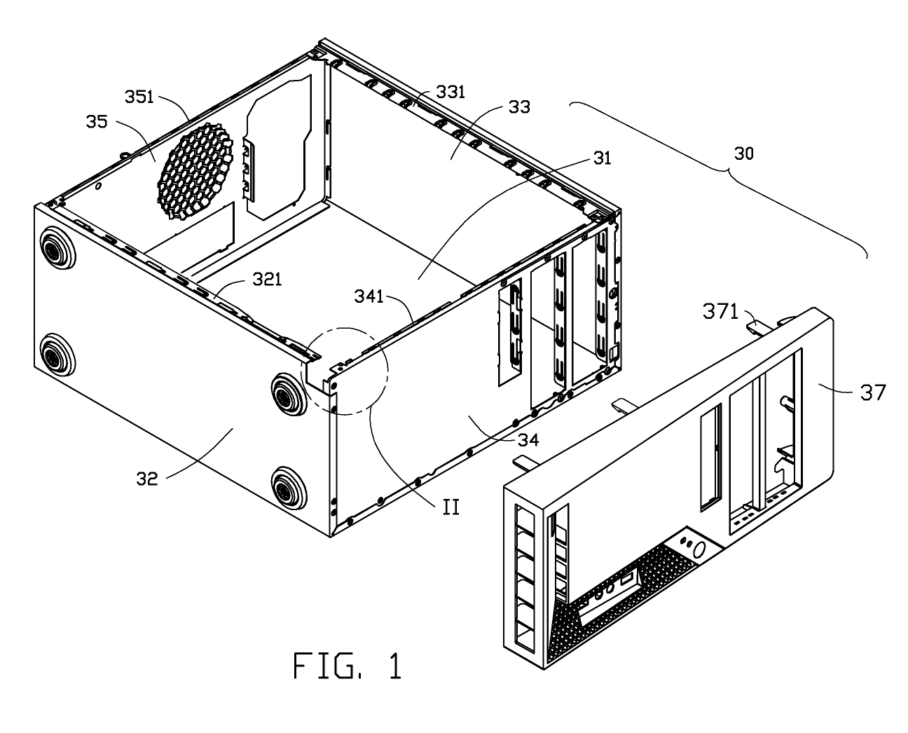

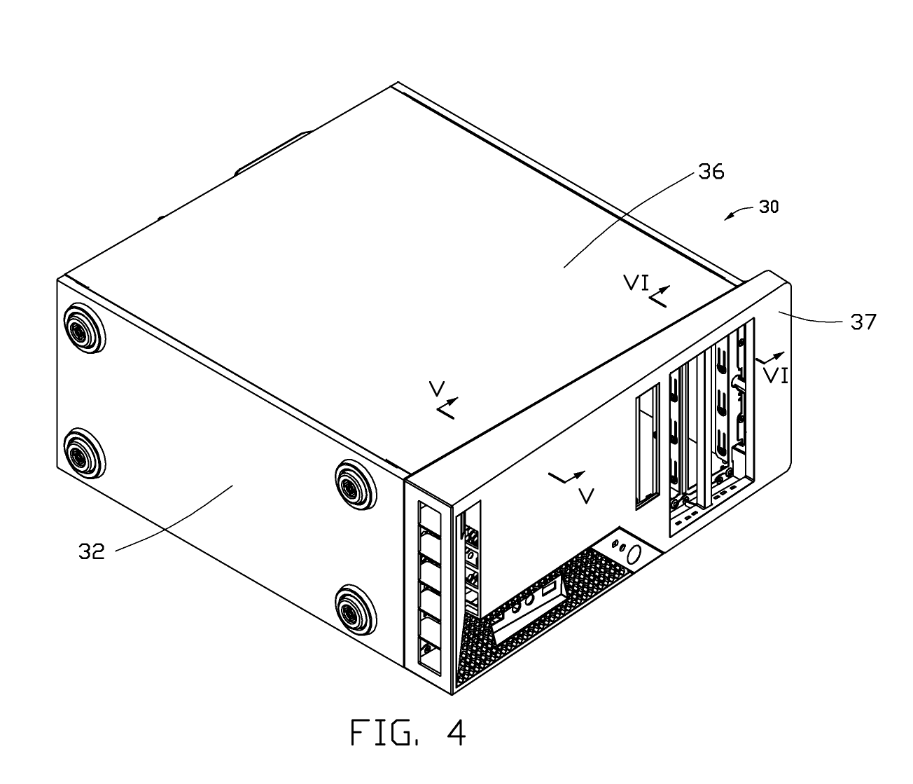

Referring to FIG. 1, an apparatus in accordance with an embodiment includes a case 30, a cover 36 (shown in FIG. 4), and a bezel 37. The case 30 includes a sidewall 31, a bottom wall 32, a top wall 33, a front wall 34, and a rear wall 35. The bottom wall 32, the top wall 33, the front wall 34, and the rear wall 35 are located on the sidewall 31. The first and top walls 32, 33 are positioned between the front wall 34 and the rear wall 35. In one embodiment, The bottom wall 32, the top wall 33, the front wall 34 and the rear wall 35 are substantially perpendicular to the sidewall 31, the bottom wall 32 is substantially parallel to the top wall 33 and perpendicular to the front wall 34 and the rear wall 35, and the front wall 34 is substantially parallel to the rear wall 35.

A first wall flange 321 is located on a top edge of the bottom wall 32. A second wall flange 331 is located on a top wall 33. A third wall flange 341 is located on the front wall 34. A fourth wall flange 351 is located on the rear wall 35. The third and fourth wall flanges 341, 351 are secured to the first and second wall flanges 321, 331.

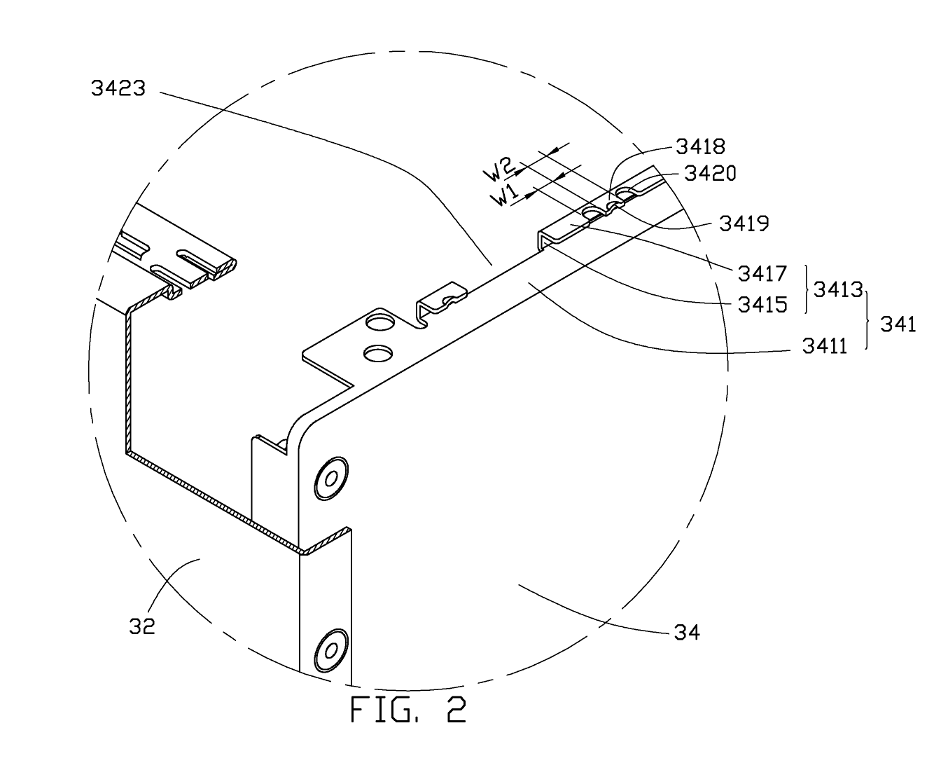

Referring to FIG. 2, the third flange 341 includes a base plate 3411 and a supporting portion 3413. The base plate 3411 extends from the front wall 34. The supporting portion 3413 is located on the base plate 3411. The supporting portion 3413 includes a connecting plate 3415 located on the base plate 3411 and a supporting plate 3417 located on the connecting plate 3415. In one embodiment, the base plate 3411 and the supporting plate 3417 are substantially perpendicular to the front wall 34, and the connecting plate 3415 is substantially parallel to the front wall 34.

A plurality of pairs of cutouts 3420 are defined in the supporting plate 3417, along a direction substantially perpendicular to the rear wall 34. An extending tab 3418 with a protrusion 3419 is located on the supporting plate 3417 between each pair of cutouts 3420 and extends in a direction substantially perpendicular to the front wall 34.

In one embodiment, each cutout 3420 has a first width W1, and each extending tab 3418 has a second width W2. The width W1 is not less than 2 mm, and not greater than 3.5 mm, and the width W2 is not less than 3 mm, and not greater than 4 mm. In another embodiment, the width W1 is not less than 2.5 mm, and the width W2 is 3.2 mm.

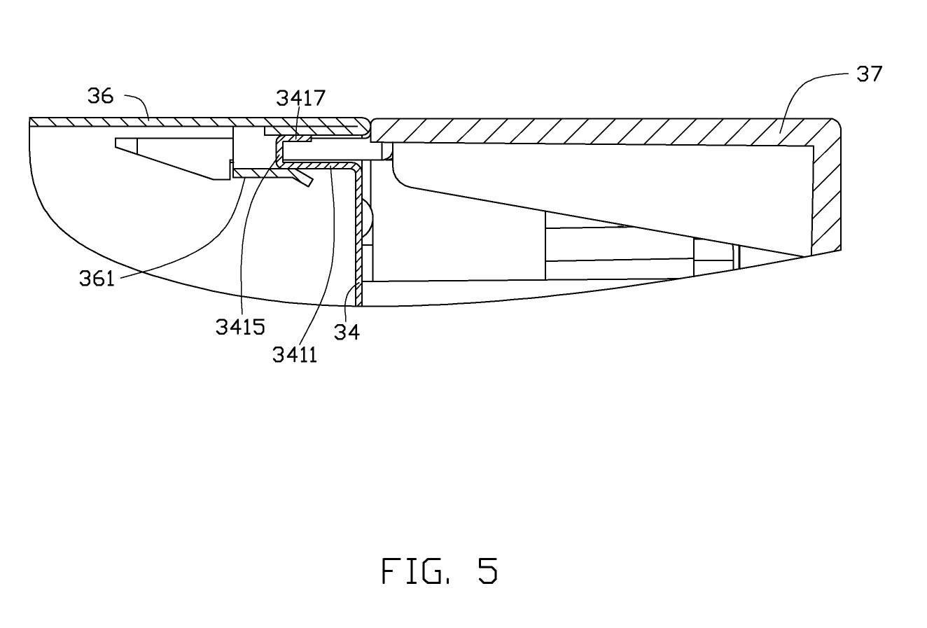

Referring to FIGS. 1-2, a plurality of receiving openings 3423 is defined in connecting plate 3415 and the supporting plate 3417 of the supporting portion 3413. A plurality of locking members 371 is located on the bezel 37, for engaging in the receiving openings 3423 of the case 30. Referring to FIG. 5, a clip 361 is located on the cover 36 for receiving the third wall flange 341.

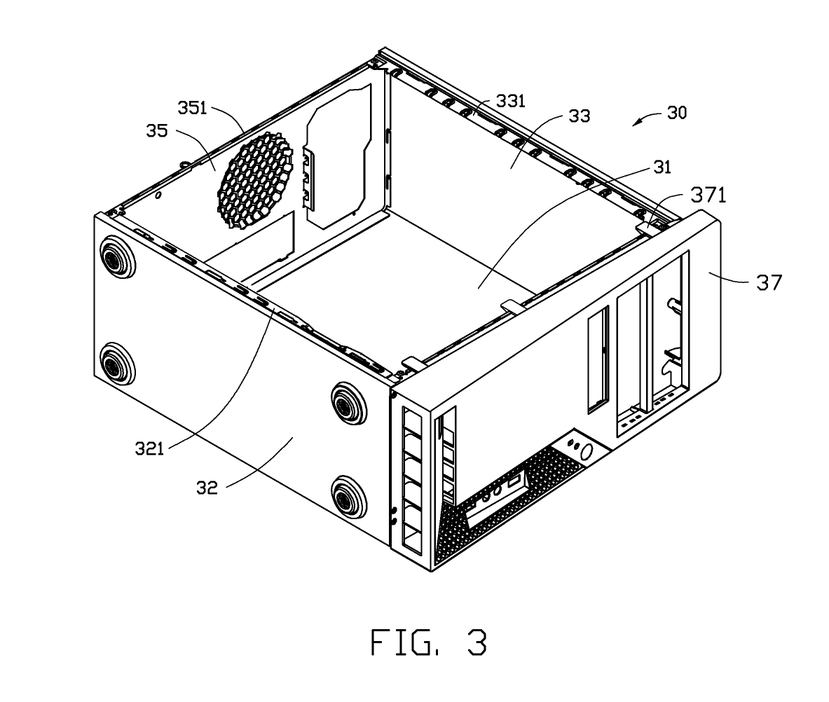

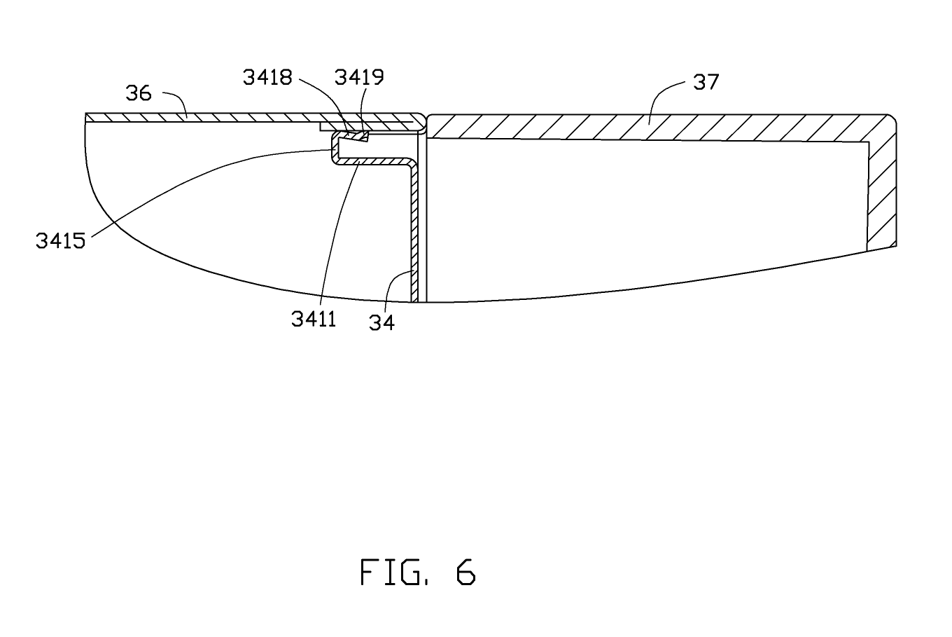

Referring to FIGS. 3-4 and 5-6, in use, the locking members 371 of the bezel 37 are locked in the receiving openings 3423 of the case 30, so as to secure the bezel 37 to the case 30. The cover 36 is secured to the case 30, with the clip 361 engaging with the third wall flange 341. The first through fourth wall flanges 321, 331, 341 and 351 contact with the cover 36, and the supporting plate 3417 and the protrusions 3419 of the extending tabs 3418 contact with the cover 36. The extending tabs 3418 are resiliently deformed. The protrusions 3419 is capable of providing better grounding between the case 30 and the cover 36 and thereby reducing EMI from passing through gaps between the cover 36 and the third flange 341 to harm users or interfere with other electronic apparatus.

Because the third wall flange 341 includes the base plate 3411 and the supporting portion 3413, so the third wall flange 341 can be reinforced. Therefore, the third flange 341 can be made of a relatively thin gauge metal, such as a 0.4 mm, and still be strong enough to secure the cover 36 of the case 30. Furthermore, the cutouts 3420 extend in a direction substantially perpendicular to the front wall 34 and have sufficient enough width, so a die, that has the same size as the width W1 of the cutouts 3420 and is used to punch the cutouts 3420, can be strong enough not to be easily damaged in the punching process. In addition, the extending tabs 3418 also have sufficient enough width, so as to be reinforced to improve EMI-resistant capability.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An apparatus comprising:
a case, the case comprising a wall, a wall flange located on the wall, the wall flange comprising a base plate and a supporting portion located on the base plate, a plurality of pairs of cutouts and a plurality of receiving openings defined in the supporting portion, an extending tab located between each pair of cutouts, a distance defined between the extending tab and the base plate; and
a bezel, a plurality of locking members located on the bezel, the locking members engaged in the receiving openings.

2. The apparatus of claim 1, wherein a width of each cutout is not less than 2 mm, and not greater than 3.5 mm.

3. The apparatus of claim 2, wherein the width of each cutout is 2.5 mm.

4. The apparatus of claim 1, wherein a width of each extending tab is not less than 3 mm, and not greater than 4 mm.

5. The apparatus of claim 4, wherein the width of each extending tab is 3.2 mm.

6. The apparatus of claim 1, wherein the base plate is substantially perpendicular to the wall.

7. The apparatus of claim 1, wherein the supporting portion comprises a connecting plate and a supporting plate; the connecting plate is substantially parallel to the wall and perpendicular to the base plate; the supporting plate is substantially perpendicular to the connecting plate; the extending tabs and the plurality of pair of cutouts are located on the horizontal portion; and the plurality of receiving openings are defined in the connecting plate and the supporting plate.

8. The apparatus of claim 1, further comprising a cover secured to the wall, the extending tabs contacting with the cover.

9. An apparatus comprising:
a case, the case comprising a wall; a wall flange located on the wall; the wall flange comprising a base plate and a supporting portion located on the base plate; the supporting portion comprising a connecting plate and a supporting plate; the connecting plate connected between the base plate and the supporting plate; a plurality of extending tabs extending from the supporting plate in a direction substantially perpendicular to the wall, for contacting with a cover; and the supporting plate and the connecting plate defining a plurality of receiving openings; and
a bezel, a plurality of locking members located on the bezel, the locking members engaged in the receiving openings.

10. The apparatus of claim 9, wherein a plurality of pair of cutouts is defined in the supporting plate; and each extending tab is located between each pair of cutouts.

11. The apparatus of claim 10, wherein a width of each cutout is not less than 2 mm, and not greater than 3.5 mm.

12. The apparatus of claim 11, wherein the width of each cutout is 2.5 mm.

13. The apparatus of claim 9, wherein a width of each extending tab is not less than 3 mm, and not greater than 4 mm.

14. The apparatus of claim 12, wherein the width of each extending tab is 3.2 mm.

15. The apparatus of claim 9, wherein the base plate is substantially perpendicular to the wall; and the supporting plate is substantially perpendicular to the base plate.

16. The apparatus of claim 15, wherein the connecting plate is substantially perpendicular to the supporting plate and the base plate.
